(19) United States
(12) Patent Application Publication
(10) Pub. No.: US 2026/0018486 A1
(43) Pub. Date: Jan. 15, 2026

(54) NEAR HERMETIC THERMAL RADIO FREQUENCY PACKAGING DEVICES, AND FABRICATION METHODS THEREOF

(71) Applicant: Qorvo US, Inc., Greensboro, NC (US)

(72) Inventors: MD Hasnine, Wylie, TX (US); Matthew Essar, Wylie, TX (US); Walid Meliane, Frisco, TX (US)

(21) Appl. No.: 19/233,636

(22) Filed: Jun. 10, 2025

Related U.S. Application Data
(60) Provisional application No. 63/669,598, filed on Jul. 10, 2024.

(51) Int. Cl. H01L 23/42; H01L 23/00; H01L 23/373; H01L 23/552

(52) U.S. Cl. CPC H01L 23/42; H01L 23/3731; H01L 23/3736; H01L 23/3738; H01L 23/552; H01L 24/32; H01L 24/33; H01L 24/29; H01L 2224/29139; H01L 2224/29144; H01L 2224/29147; H01L 2224/32225; H01L 2224/32245; H01L 2224/33181

(57) ABSTRACT

The present disclosure provides a packaging device and a method to form the packaging device. The packaging device includes a package base, a die structure disposed over the package base, and a package lid over the die structure. The package lid is thermally coupled with the die structure and the package base.

### CROSS-REFERENCE TO RELATED APPLICATION(S)

The present application claims the benefit of U.S. Provisional Application No. 63/669,598, entitled “NEAR HERMETIC THERMAL RADIO FREQUENCY PACKAGING DEVICES, AND FABRICATION METHODS THEREOF” and filed on Jul. 10, 2024, which is hereby incorporated by reference in its entirety.

### FIELD OF THE INVENTION

This disclosure relates to radio frequency (RF) packaging technologies. In particular, this disclosure relates to near hermetic thermal RF packaging devices, and method for forming these devices.

### BACKGROUND

Radio frequency (RF) technology forms the backbone of modern telecommunications, wireless networking, and countless electronic devices we rely on daily. At its core, RF technology involves the generation, transmission, and reception of radio waves across a spectrum of frequencies, enabling communication over short and long distances without the need for physical wires. The functionalities of different modules of a RF device are implemented by numerous dies with various different RF components. To protect the dies from being damaged or contaminated, the dies are often packaged in proper materials.

For example, in RF packages, thermal dissipation and hermeticity are two aspects that are crucial to the reliability and performance of the packaged RF devices. RF components generate heat during operation, which can degrade signal integrity, increase noise levels, and ultimately lead to device failure if not properly managed. Efficient heat dissipation ensures that temperatures remain within safe operating limits, preserving the stability and longevity of RF packages. Also, hermeticity plays a critical role in ensuring the reliability and longevity of RF packages by preventing moisture and contaminants from entering sensitive electronic components. However, existing RF packages might not meet the thermal dissipation and hermeticity requirements for rapidly advancing RF technologies.

Therefore, there is a need to improve the thermal dissipation and hermeticity in RF packages.

### SUMMARY

Aspects of the disclosure include a packaging device. The packaging device includes a package base, a die structure disposed over the package base, and a package lid over the die structure. The package lid is thermally coupled with the die structure and the package base.

In some embodiments, the package lid comprises a hermetic material having a thermal conductivity of at least 180 W/(m·K).

In some embodiments, the package lid comprises at least one of silicon carbide, ceramic, or copper.

In some embodiments, the package base comprises at least one of silicon carbide, ceramic, or copper.

In some embodiments, the packaging device further includes a first thermal interface layer disposed between the die structure and the package lid. The first thermal interface layer is in contact with the die structure and the package lid.

In some embodiments, the first thermal interface layer comprises at least one of sintered gold, sintered silver, or sintered copper.

In some embodiments, the packaging device further includes a second thermal interface layer disposed between the die structure and the package base. The second thermal interface is in contact with the die structure and the package base.

In some embodiments, the second thermal interface layer comprises at least one of sintered gold, sintered silver, or sintered copper.

In some embodiments, the second thermal interface layer comprises an interposer layer that electrically connects the die structure and the package base.

In some embodiments, the packaging device further includes a third thermal interface layer disposed between the package lid and the package base. The third thermal interface is in contact with the package lid and the package base.

In some embodiments, the third thermal interface layer comprises at least one of sintered gold, sintered silver, or sintered copper.

In some embodiments, the packaging device further includes a molding layer surrounding and in contact with a side surface of the package lid.

In some embodiments, the packaging device further includes a metal shielding layer covering the molding layer.

In some embodiments, the packaging device further includes a metal shielding layer in contact with a top surface and a side surface of the package lid, and a molding layer covering the metal shielding layer.

In some embodiments, the metal shielding layer comprise a copper-stainless steel-copper structure.

In some embodiments, the die structure comprises, a semiconductor die, a package substrate, and an interconnect layer between the semiconductor die and the package substrate. The interconnect layer electrically connects the semiconductor die and the package substrate.

In some embodiments, the interconnect layer comprises a plurality of soldering structures without an underfill layer.

In some embodiments, the package base comprises a plated heat spreader (PHS) substrate.

In some embodiments, the package base comprises a lead frame or a copper substrate.

Aspects of the present disclosure also provide method for forming a packaging device. The method includes forming a die structure, forming a package base, forming a package lid, bonding the die structure onto the package base, and bonding the package lid onto the package base and the die structure.

In some embodiments, the method further includes forming a thermal interface layer over the package base. The bonding of the die structure onto the package base comprises bonding the die structure onto the thermal interface layer via metal-to-metal bonding.

In some embodiments, the method further includes forming a second thermal interface layer over the die structure and a third thermal interface layer over a peripheral area of the package base. The bonding of the package lid onto the package base and the die structure comprises bonding the package lid onto the second thermal interface layer and the third thermal interface layer via metal-to-metal bonding.

In some embodiments, the method further includes forming a molding layer surrounding a side surface of the package lid via film-assisted molding.

In some embodiments, the method further includes forming a metal shielding layer through sputtering shielding.

In some embodiments, the forming of the die structure comprises soldering a semiconductor die onto a package substrate without forming an underfill layer.

### BRIEF DESCRIPTION OF THE DRAWINGS

FIG. 1 illustrates an existing RF package.

FIGS. 2-6 each illustrates an exemplary RF packaging device, according to embodiments of the present disclosure.

FIGS. 7A-7G illustrate different stages of a fabrication process to form a RF packaging device, according to embodiments of the present disclosure.

FIG. 8 illustrates a flowchart of an exemplary fabrication process for forming a RF packaging device, according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., +10%, +20%, or +20% of that value, or +30%).

Reference will now be made in greater detail to various embodiments of the subject matter of the present disclosure, some embodiments of which are illustrated in the accompanying drawings.

Laminate air cavity packages are utilized in RF high-power applications due to air's superior dielectric properties compared to mold compounds, offering significant RF performance advantages. In these RF high-power packages, plastic lids are used. However, plastic air cavity packages are vulnerable to gross leak (GL) testing when exposed to environmental conditions such as moisture sensitivity level (MSL) pre-conditioning. During board-level assembly, the cavity package undergoes multiple reflows and aqueous washes. Compliance with MSL and GL standards ensures that liquids cannot enter the cavity, thereby protecting the package from corrosion, maintaining RF performance, and more. Given that plastic packages are more susceptible to GL, a solution is needed to make the cavity package resistant to GL, approaching near-hermetic or hermetic levels.

On the other hand, as the gate of gallium nitride (GaN) devices decreases, there is a corresponding increase in concentrated heat flux. Effectively managing device heating and controlling the junction temperature becomes crucial, as these factors can significantly impact performance and reliability. Relying solely on heat sinks may be insufficient for dissipating highly concentrated heat flux. In high-power RF packages with Cu pillars and solder caps, the ability to dissipate heat through the package laminate is limited, leading to high thermal resistance, and ultimately degrading the device's lifetime. Therefore, an alternative cooling method, such as top-side cooling, may be used to establish an enhanced thermal pathway to the ambient environment.

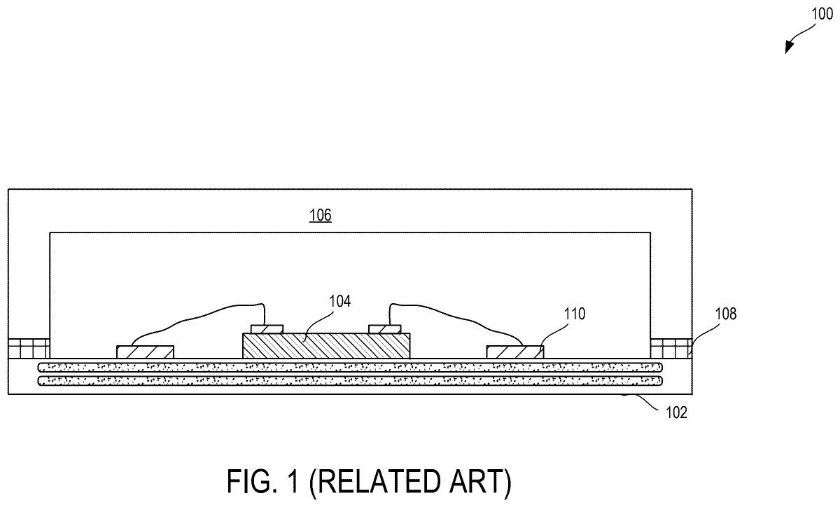

FIG. 1 shows an existing RF package 100 with a plastic lid. RF package 100 can be an example of a laminate air cavity package. As shown in FIG. 1, RF package 100 includes a substrate 102, a die 104 disposed over substrate 102, and a lid 106 over die 104. Die 104 can be attached to substrate 102 via a suitable adhesive, and can be electrically connected to substrate 102 (or another component 110 over substrate 102) through wire bonding. Lid 106 includes plastic, and is fixed onto substrate 102 via a scaling layer 108, such as epoxy. Die 104 has no contact with lid 106. Heat generated by die 104 is often transmitted through the adhesive and to substrate 102, which can include silicon, plastic, glass, polymer, dielectric, copper, etc. For example, the space between die 104 and lid 106 is filled with air. As described above, lid 106 and sealing layer 108 may have undesirable hermeticity, while the thermal dissipation solely depending on substrate 102 may not be sufficient.

Embodiments of the present disclosure provide a cavity packaging technique that approaches near-hermetic levels. In an example, the packaging device includes a flip chip (FC) e.g., a GaN/GaAs copper pillar (CuP), an oversized heat spreader with cavity walls, a flip-chip substrate, and a base substrate such as SiC, plated heat spreader (PHS), and lead frame (LF). The FC die can be attached to the substrate, which is then connected to the base substrate using a high thermal conductivity sintering material, such as sintered gold. The oversized heat spreader with cavity walls is then attached to the top of the die and the base substrate using a high thermal conductivity sintering material, such as sintered Au. This configuration brings the cavity package closer to near-hermetic levels. The oversized semiconductor heat spreader on top of the die allows for top-side cooling, providing an efficient path for extracting heat and significantly reducing the junction temperature. Moreover, a package nearing hermetic levels can enhance RF performance. For example, during board-level assembly, the module can be washed without the risk of liquid entering inside.

The process begins by attaching the FC (e.g., a high-power GaN or GaAs die) to a top substrate using flux print or dipping, followed by reflow and cleaning. An underfill process is then employed to ensure the integrity of the stacked FC die. After surface mount technology (SMT) and underfilling, the module is attached to a base substrate such as SiC, PHS, or LF using sintered Au. Then, an oversized SiC heat spreader with cavity walls is bonded to the top of the die and the base substrate using a high thermal conductivity sintering material, such as sintered Au. This results in a package with an exposed heat spreader on top, creating a cavity package that approaches near-hermetic levels. Alternatively of additionally, film-assisted molding and/or sputter shielding can be used to ensure the integrity of the cavity package hermeticity and integrity of the heat spreader. The disclosed method allows customers to attach heat sinks to the top, while the bottom package can be mounted on a PCB. As a result, it enables top-side cooling through the heat spreader and forms a closed cavity close to near-hermetic or hermetic levels. Overall, the disclosed packaging devices and fabrication methods enhance heat transfer within the package and improves the RF performance of the cavity package.

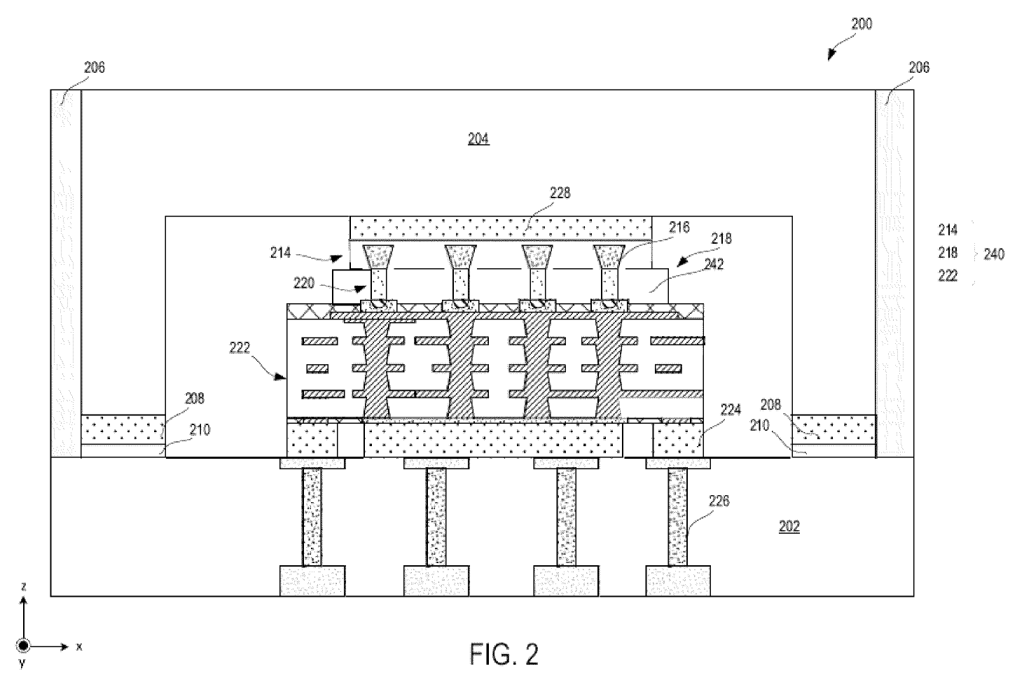

FIGS. 2-6 show various packaging devices 200-600 with improved thermal conductivity and/or hermeticity. FIG. 2 illustrates an exemplary packaging device 200 according to embodiments of the present disclosure.

Packaging device 200 may include a package base 202, a die structure 240 disposed over package base 202, and a package lid 204 over die structure 240. Package lid 204, also referred to as a heat spreader or an oversized heat spreader in this disclosure, may be thermally coupled with die structure 240 and package base 202. In some embodiments, die structure 240 may include a semiconductor die 214, a package substrate 222, and an interconnect layer 218 between semiconductor die 214 and package substrate 222. Interconnect layer 218 may electrically connect semiconductor die 214 and package substrate 222.

Package base 202 may include at least one of silicon carbide (SiC), ceramic, and copper (Cu). Package base 202 may have improved hermeticity and/or thermal conductivity than an existing package base (e.g., 102). In some embodiments, package base 202 includes SiC. Package base 202 may include a plurality of inputs/output s (or I/O's) 226 for transmitting signals generated by semiconductor die 214 (through package substrate 222) to an external circuit. In some embodiments, I/O's 226 includes any suitable conductive wirings, interconnects, vias, etc. I/O's 226 may include suitable conductive materials such as copper (Cu), aluminum (Al), tin (Sn), gold (Au), silver (Ag), and so on.

Semiconductor die 214 may include various structures and/or devices for implementing certain functions. For example, semiconductor die 214 may include one or more RF and/or electrical components such as RF filters, transmitters, receivers, transceivers, amplifiers, etc. In an example, semiconductor die 214 may include a FC that includes a high-power GaN/GaAs die with CuP. Semiconductor die 214 may also include a plurality of interconnect structures 216 for transmitting various types of signals, e.g., RF signals, optical signals, electrical signals, etc. For example, interconnect structures 216 include metallization layers, vias, or a combination thereof. In operation, semiconductor die 214 may generate heat by its components. Interconnect structure 216 may be electrically connected with package substrate 222 for transmitting certain signals as designed. In some embodiments, interconnect structures 216 may include various vias and/or wirings that include suitable conductive materials such as copper (Cu), aluminum (Al), tin (Sn), gold (Au), silver (Ag), and so on.

Interconnect layer 218 may include a plurality of soldering structures 220 in underfill layer 242. Soldering structures 220 may be in contact with interconnect structures 216 and any corresponding interconnects of package substrate 222, providing electrical connection between semiconductor die 214 and package substrate 222. In some embodiments, soldering structures 220 includes copper pillars and/or solder caps. Underfill layer 242 may include an underfill material such as an suitable adhesive. Examples of underfill layer 242 may include: a thermally conductive or thermally non-conductive material such as a resin-based material In various embodiments, underfill layer 242 provides support and stability for semiconductor die 214. In some embodiments, underfill layer 242 and/or soldering structures 220 dissipate heat from semiconductor die 213 to package substrate 222.

Package substrate 222 may include suitable wirings for providing electrical connection between semiconductor die 214 and an external circuit. In some embodiments, package substrate 222 includes a laminate with a plurality of embedded conductive wirings that are electrically connected to soldering structures 220, which are electrically connected to semiconductor dic 214. The embedded conductive wirings may include a suitable metal such as copper (Cu), aluminum (Al), tin (Sn), gold (Au), silver (Ag), or a combination thereof. In some embodiments, heat generated by semiconductor dic 214 may be transmitted to package substrate 222 through soldering structures 220 and/or underfill layer 242.

Package lid 204 may include a material that has desirably high thermal conductivity while provides sufficiently high hermeticity. In various embodiments, package lid 204 includes a hermetic material having a thermal conductivity of at least 180 W/(m·K). In some embodiments, package lid 204 includes at least one of ceramic and copper (Cu). In some embodiments, package lid 204 includes a wide bandgap semiconductor material such as silicon carbide (SiC), diamond, gallium nitride (GaN), and/or aluminum nitride (AlN). In some embodiments, the selection of material(s) for package lid 204 includes consideration of the case/convenience of fabrication. For example, because GaN device is grown on SiC substrate and if a lid includes a wide band gap semiconductor material such as SiC, the SiC may have a matching coefficient of thermal expansion (CTE) as the GaN dic. The impact of thermal expansion of structures due to temperature change can be minimized. As shown in FIG. 2, package lid 204 may surround/enclose die structure 240 in the x-y plane (e.g., at least substantially parallel to package base 202) and in the z-direction (e.g., at least substantially vertical to the x-y plane). For case of illustration, package lid 204 includes a top surface extending in the x-y plane and a side surface (e.g., also referring as “walls”) extending in the z-direction.

Packaging device 200 may include a thermal interface layer 228 disposed between package lid 204 and die structure 240 (e.g., semiconductor die 214) for dissipating at least part of the heat generated by die structure 240. In some embodiments, thermal interface layer 228 is in contact with package lid 204 (e.g., at its top surface) and semiconductor dic 214 to form the thermal coupling between package lid 204 and semiconductor die 214. For example, heat generated by semiconductor dic 214 can be dissipated to package lid 204 through thermal interface layer 228. Thermal interface layer 228 may have a desirably high thermal conductivity of at least 150 W/(m·K). In some embodiments, thermal interface layer 228 includes at least one of sintered gold, sintered silver, and sintered copper. For example, thermal interface layer 228 includes sintered gold.

Packaging device 200 may also include a thermal interface layer 224 disposed between dic structure 240 (e.g., package substrate 222) and package base 202. In some embodiments, thermal interface layer 224 includes an interposer and is electrically coupled to package substrate 222 and package base 202. For example, thermal interface layer 224 is in contact with package substrate 222 and package base 202. In some embodiments, heat generated by semiconductor die 214 can be dissipated to package base 202 through package substrate 222 and thermal interface layer 224. Thermal interface 224 may function as an adhesive layer that attaches package substrate 222 to package base 202, and have a desirably high thermal conductivity of at least 150 W/(m·K). In some embodiments, thermal interface layer 224 includes at least one of sintered gold, sintered silver, and sintered copper. For example, thermal interface layer 224 includes sintered gold.

Packaging device 200 may also include a thermal interface layer 208 disposed between package lid 204 and package base 202. In some embodiments, thermal interface layer 208 is in contact with package lid 204 and a surface finish layer 210 of package base 202 to fully enclose dic structure 240 in packaging device 200. In some embodiments, surface finish layer 210 includes electroless nickel immersion gold (ENIG or Au/Ni) and/or immersion silver (Ag) Thermal interface layer 208 may include a material of desirably high thermal conductivity (for conducting heat for package lid 204) and hermeticity (for preventing moisture and contamination from leaking inside packaging device 200). Thermal interface layer 208 may have a desirably high thermal conductivity of at least 150 W/(m·K). In some embodiments, thermal interface layer 208 includes at least one of sintered gold, sintered silver, and sintered copper. For example, thermal interface layer 208 includes sintered gold. In some embodiments, the space between package lid 204 and die structure 240, where not filled with thermal interface layers 224 and 228, is filled with air.

In some embodiments, packaging device 200 further includes a molding layer 206 surrounding and in contact with the side surface of package lid 204. A thickness of molding layer 206 may be in range of about 30 μm and about 100 μm. In some embodiments, the top surface of package lid 204 is not covered by any molding layer. In some embodiments, molding layer 206 improves the hermeticity and mechanical support of packaging device 200.

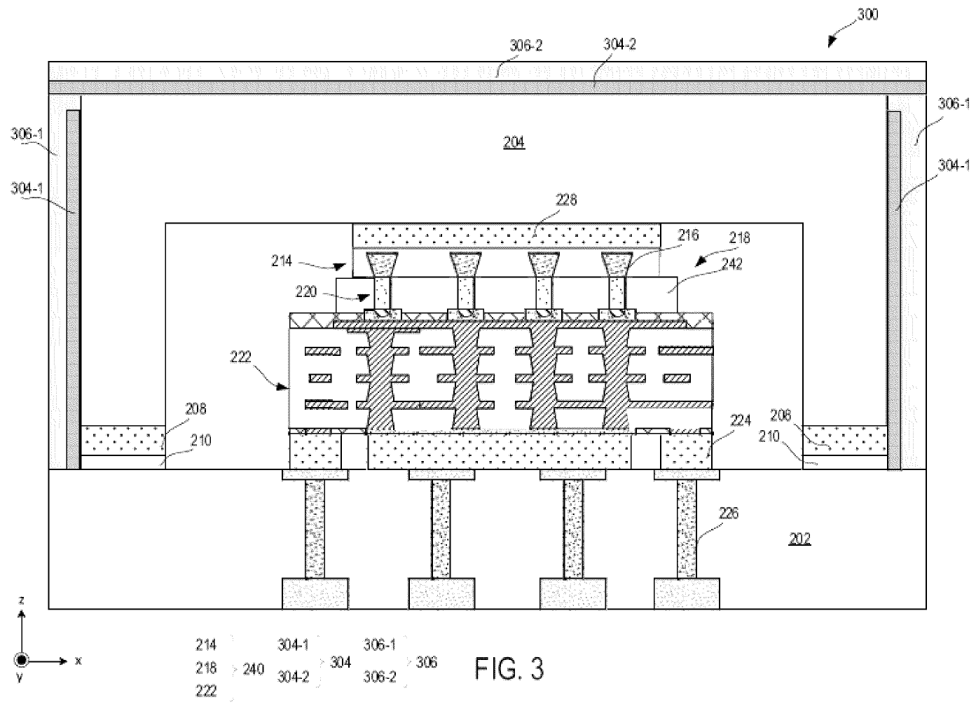

FIG. 3 shows packaging device 300, according to embodiments of the present disclosure. Different from packaging device 200, packaging device 300 may include a metal shielding layer 304 that partially or fully covers package lid 204. As shown in FIG. 3, metal shielding layer 304 may include a first portion 304-1 that partially or fully covers the side surface of package lid 204, and a second portion 304-2 that partially or fully covers the top surface of package lid 204. In various embodiments, first portion 304-1 and second portion 304-2 may or may not be in contact with each other. For example, first portion 304-1 and second portion 304-2 may be in contact with each other and fully enclose package lid 204. Metal shielding layer 304 may include a copper-stainless steel-copper (Cu/SUS/Cu) structure, and may further improve the hermeticity and/or thermal conductivity of packaging device 300. In some embodiments, metal shield layer 304 also improves the integrity (e.g., mechanical strength, ability to shield itself from any environmental contamination, etc.) of package lid 202. In some embodiments, a thickness of metal shielding layer 304 is in a range of about 4 μm and about 4.5 μm.

In some embodiments, packaging device 300 further includes a molding layer 306 surrounding and in contact metal shielding layer 304. For example, molding layer 306 may include a first portion 306-1 in contact with (e.g., covering) first portion 304-1 of metal shielding layer 304, and a second portion 306-2 in contact with (e.g., covering) second portion 304-2 of metal shielding layer 304. In some embodiments, first portion 306-1 may fully cover first portion 304-1. In some embodiments, second portion 304-2 may be in contact with first portion 306-1. For example, second portion 304-2 and first portion 306-1 may fully cover package lid 204, as shown in FIG. 3. A thickness of molding layer 306 may be in range of about 30 μm and about 100 μm. In some embodiments, molding layer 306 further improves the hermeticity and mechanical support of packaging device 300.

In some embodiments, 306 may represent a metal shielding layer (e.g., 306-1 and 306-2 representing the first and second portions of the metal shielding layer), while 304 may represent a molding layer (e.g., 304-1 and 304-2 representing the first and second portions of the molding layer). In other words, a metal shielding layer may partially or fully cover the molding layer.

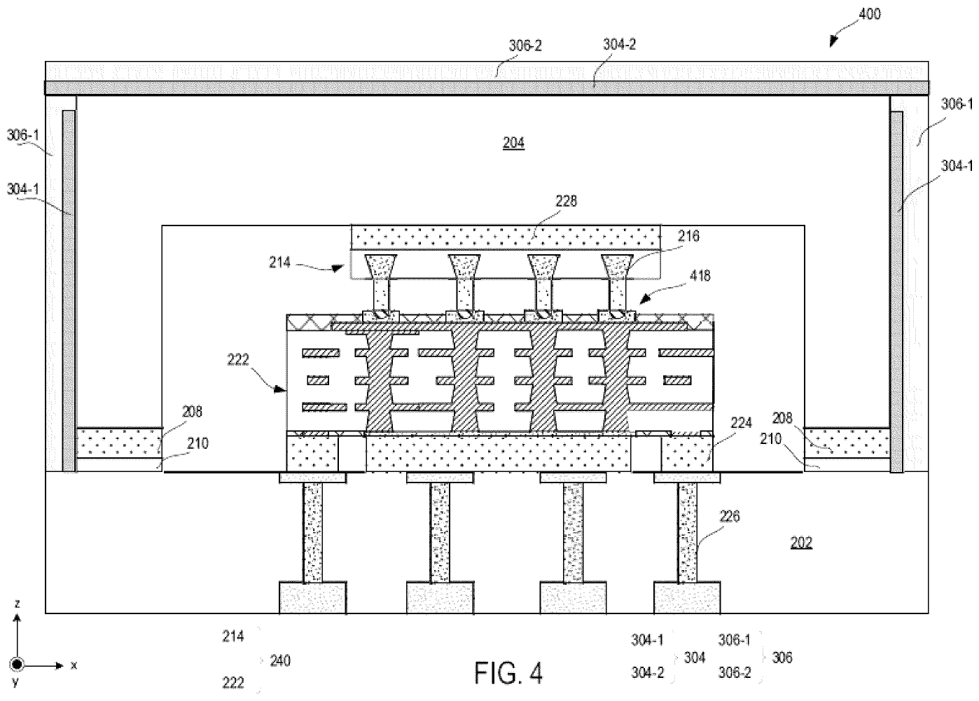

FIG. 4 shows packaging device 400, according to embodiments of the present disclosure. Different from packaging device 300, packaging device 400 includes an interconnect layer 418 that includes a plurality of soldering structures 220 but without an underfill layer (e.g., 242). In some embodiments, metal shielding layer 304 provides sufficiently high hermeticity and integrity of package lid 204 that no underfill layer is needed.

In some embodiments, packaging device 400 does not include metal shielding layer 304. For example, packaging device 400 does not include an underfill layer and any metal shielding layer, but includes a molding layer in contact with package lid 204, similar to that of packaging device 200.

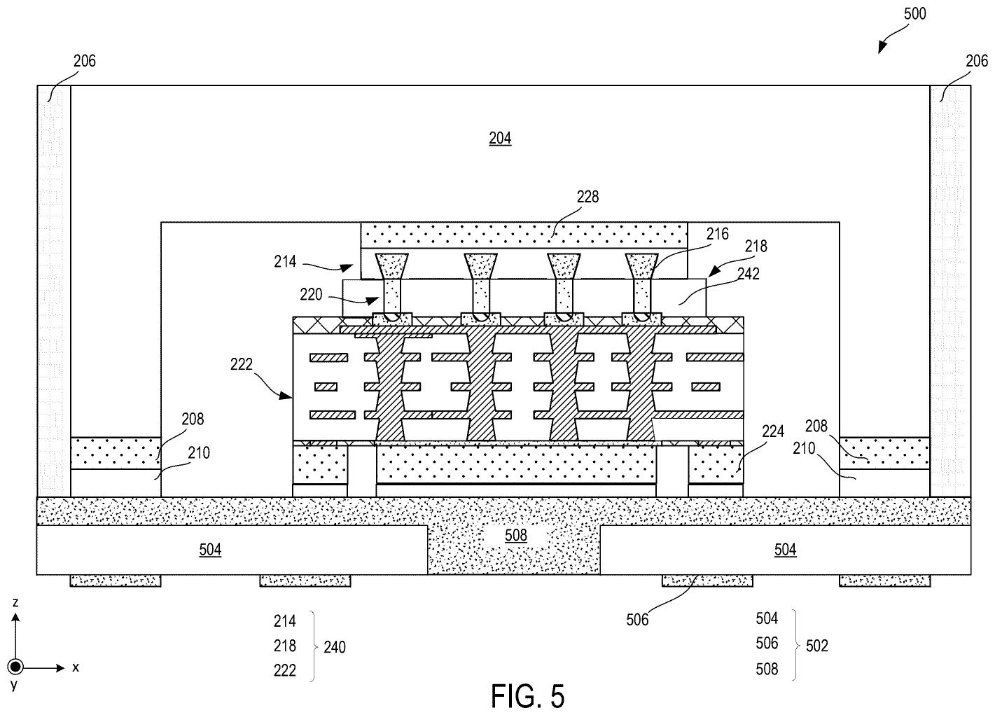

FIG. 5 shows packaging device 500, according to embodiments of the present disclosure. Different from packaging device 200, packaging device 500 includes a package base 502 that includes a plated heat spreader substrate (PHS). For example, package base 502 may include a PHS substrate 504 with embedded heat spreader 508. Package base 502 may include I/O's 506 distributed in PHS substrate 504. PHS substrate 504 may improve the thermal conductivity of packaging device 500, by more effectively dissipating heat transmitted by package lid 202. In some embodiments, PHS substrate 504 includes laminate that includes polymer, dielectric, and/or copper. In some embodiments, embedded heat spreader 508 includes copper (Cu), copper-molybdenum-copper (Cu—Mo—Cu), and/or aluminum nitride (AlN).

In various embodiments, packaging device 500 may include a single molding layer 206, or a combination of a molding layer and a metal shielding layer (similar to 304 and 306 of packaging device 400). The molding layer and/or the metal shielding layer may improve the hermiticity of package device 500 against GL. The detailed description can be referred to their counterparts in packaging devices 200 and 300, and is not repeated herein.

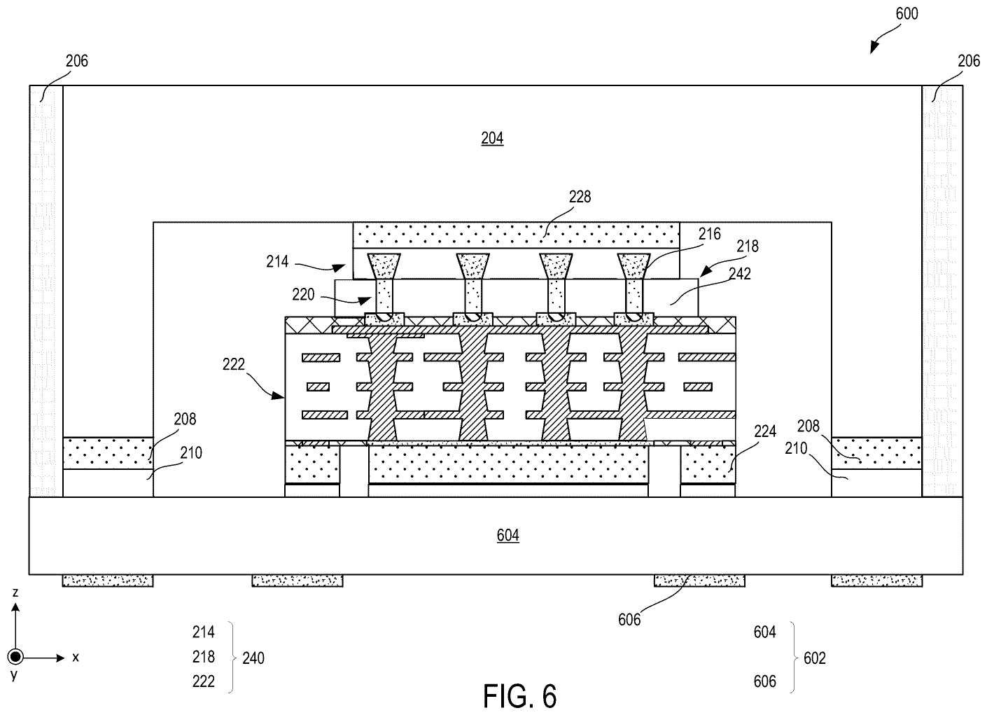

FIG. 6 shows packaging device 600, according to embodiments of the present disclosure. Different from packaging device 200, packaging device 500 includes package base 602 that includes a lead frame (LF) and/or copper (Cu) substrate 604 and a plurality of I/O's 606 distributed in substrate 604. LF and copper may improve the thermal conductivity and/or hermiticity of packaging device. In various embodiments, packaging device 600 may include a single molding layer 206, or a combination of a molding layer and a metal shielding layer (similar to 304 and 306 of packaging device 400). The molding layer and/or the metal shielding layer may improve the hermiticity of package device 600 against GL. The detailed description can be referred to their counterparts in packaging devices 200 and 300, and is not repeated herein.

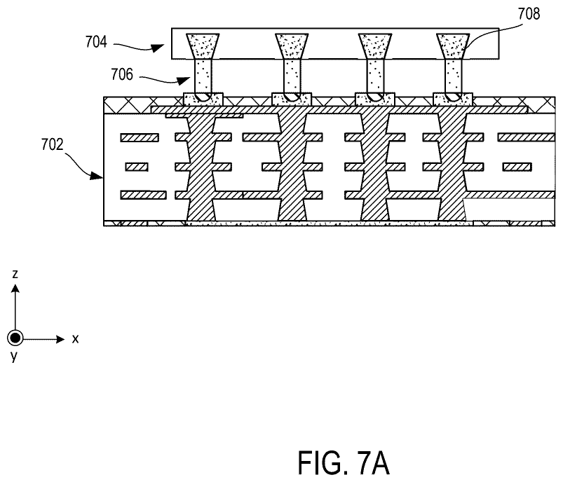

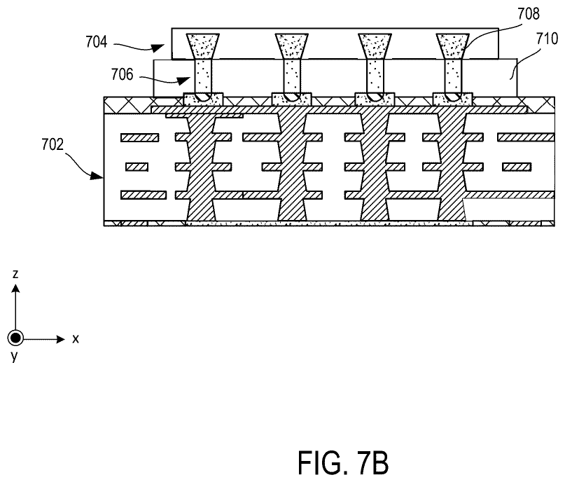

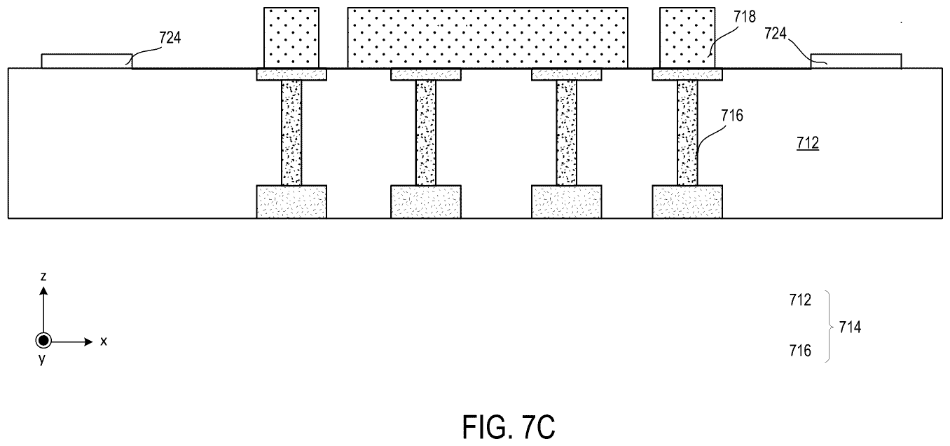

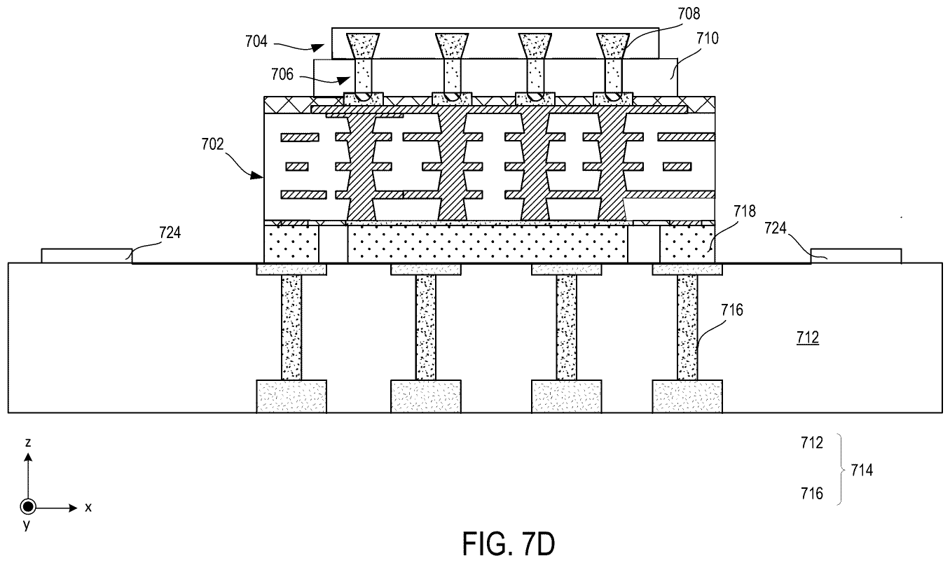

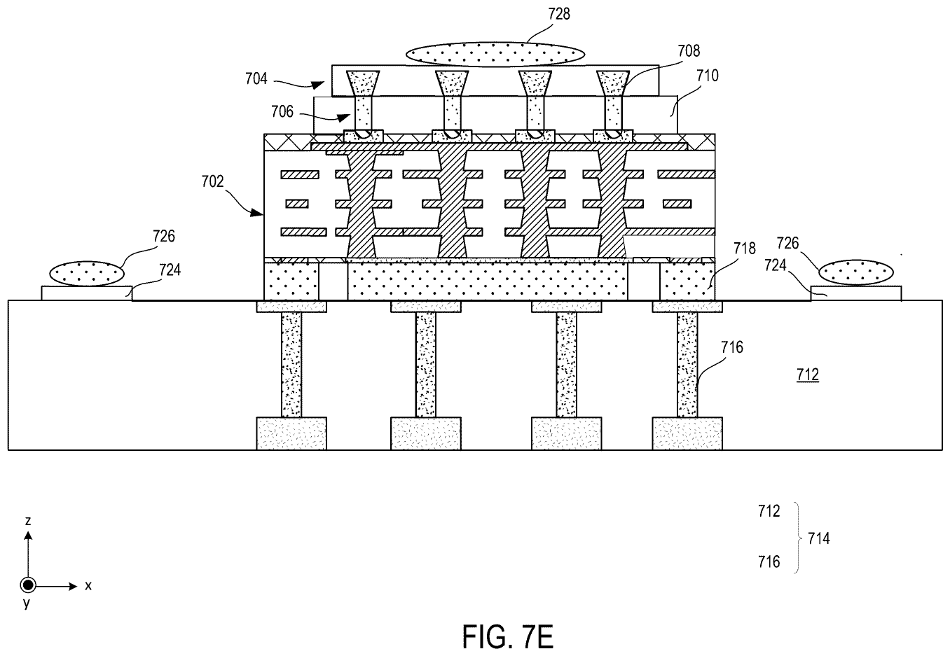

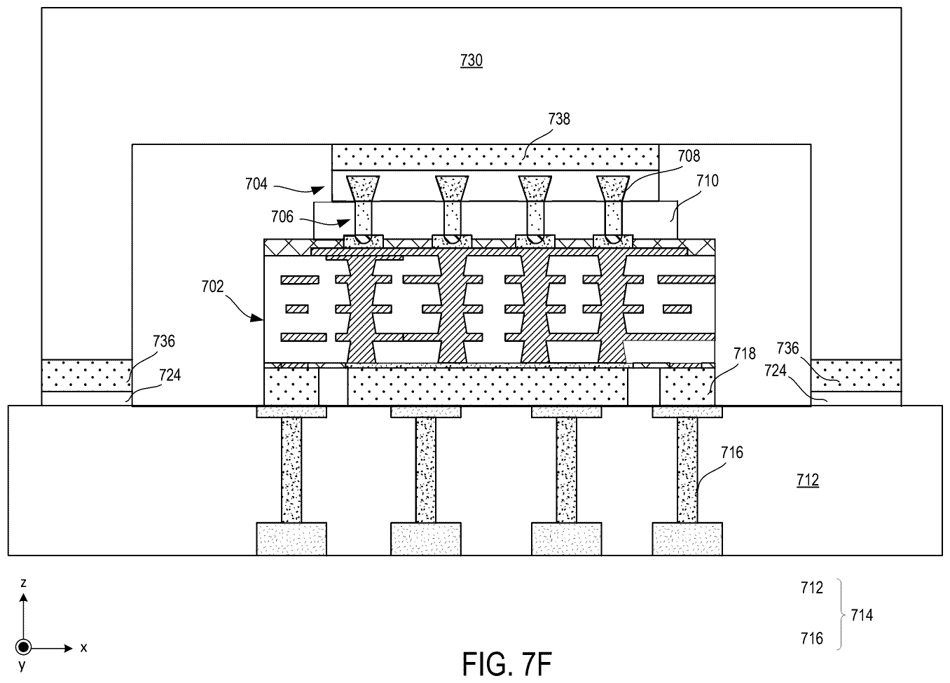

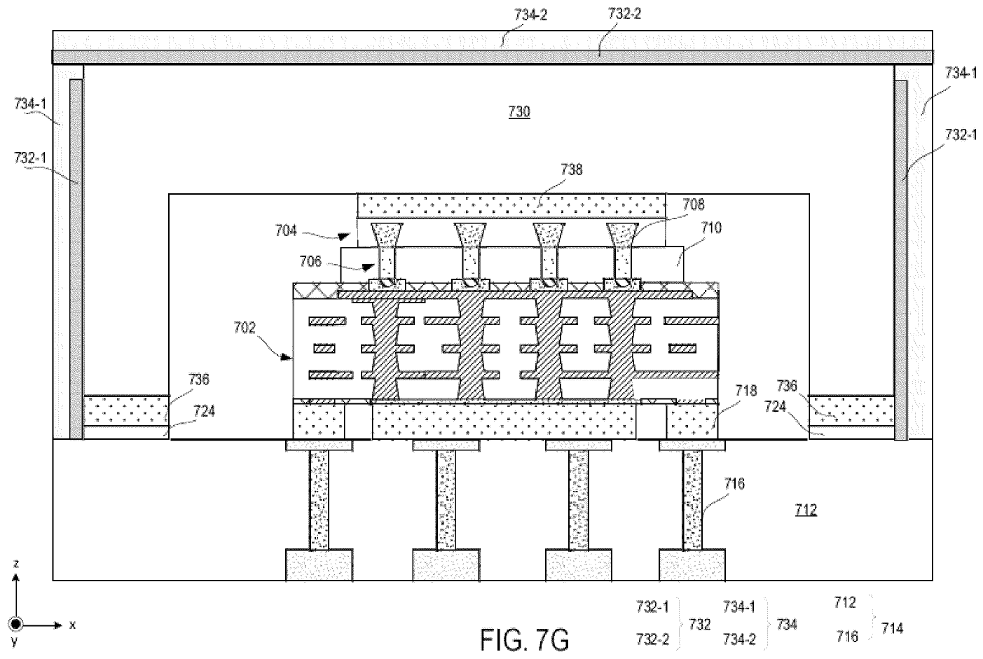

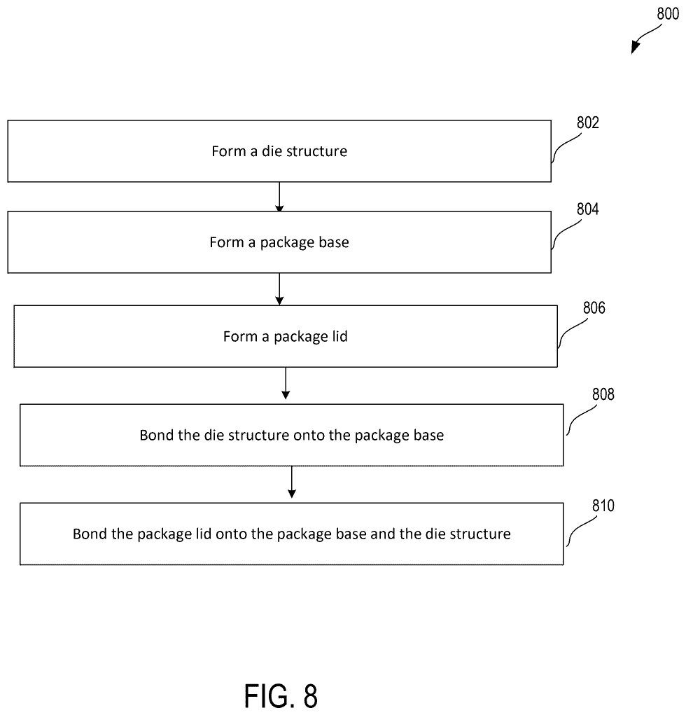

FIGS. 7A-7G illustrate structures of the packaging device at different stages a fabrication process, according to embodiments of the present disclosure. FIG. 8 is a flowchart of a method 800 for forming a packaging device shown in FIGS. 7A-7G, according to some embodiments of the present disclosure. The packaging device may be an example of one or more of packaging devices 200-600. Method 800 is merely an example, and is not intended to limit the present disclosure beyond what is explicitly recited in the claims. Additional operations can be provided before, during, and after the method 800, and some operations described can be replaced, eliminated, or moved around for additional embodiments of method 800. Method 800 will be described in more detail below.

At step 802, a die structure is formed. As shown in FIG. 7A, a semiconductor die 704 may be formed and bonded/attached onto a package substrate 702. Semiconductor die 704 may include a plurality of interconnect structures 708 (e.g., such as metallization layers, vias, etc.), and may be bonded onto package substrate 702 by soldering, e.g., forming a plurality of soldering structures 706 (e.g., copper pillars with solder caps) that are electrically connected to interconnect structures 708 and the wirings of package substrate 702. Package substrate 702 may include a laminate with a plurality of embedded metal wirings. In some embodiments, package substrate 702 and semiconductor die 704 are fabricated separately.

In some embodiments, the fabrication of semiconductor die 704, package substrate 702, and their bonding may include various RF components, and may be formed using fabrication methods such as photolithography, dry etch, wet etch, chemical vapor deposition (CVD), physical vapor deposition (PVD), atomic layer deposition (ALD), electroplating, electroless plating, sputtering, soldering, grinding, chemical mechanical polishing (CMP), flux print, dic placement, a reflow process, and a cleaning process, or a combination thereof.

As shown in FIG. 7B, an underfill layer 710 is formed between semiconductor die 704 and package substrate 702. In some embodiments, underfill layer 710 includes a resin-based material, and is formed by a material dispensing process and a curing process. In some embodiments, underfill layer 710 and soldering structures 706 may form an interconnect layer. The interconnect layer, semiconductor die 704, and package substrate 702 may form a die structure. In some embodiments, no underfill layer is formed.

At step 804, a package base may be formed. As shown in FIG. 7C, a package base 714, including a base substrate 712, and a plurality of I/O's 716 are formed. In various embodiments, base substrate 712 includes silicon carbide (SiC), ceramic, copper (Cu), a PHS substrate, a LF substrate, or a combination thereof. Base substrate 712 may include a surface finish layer 724 disposed in the area where a package lid is subsequently bonded with the package base. For example, surface finish layer 724 may be disposed in a peripheral area on base substrate 712, surrounding the die structure. In some embodiments, a thermal interface layer 718 is formed over base substrate 712. Thermal interface layer 718 may be a patterned layer with a conductive material, and may be in contact with the I/O's 716 that are exposed on base substrate 712. In some embodiments, thermal interface layer 718 includes one or more of sintered gold, sintered silver, and sintered copper.

In some embodiments, the fabrication of the package base may include one or more of photolithography, dry etch, wet etch, CVD, PVD, ALD, electroplating, electroless plating, sputtering, soldering, grinding, CMP, etc. The dispensing of thermal interface layer 718 may include dispensing a desired volume of a thermal interface material based on bond-line thickness, e.g., using a syringe with a desired nozzle diameter.

At step 806, a package lid is formed. A package lid may be formed separately to include a top surface and a side surface in contact with the top surface. For example, the package lid may include a heat spreader with cavity walls. In some embodiments, the package lid includes one or more of SiC, ceramic, and copper. The fabrication of the package lid may include one or more of photolithography, dry etch, wet etch, CVD, PVD, ALD, electroplating, electroless plating, sputtering, soldering, grinding, CMP, etc.

At step 808, the die structure is bonded onto the package base. As shown in FIG. 7D, the die structure is bonded onto package base 714 through thermal interface layer 718. In some embodiments, the bonding process may include applying heat and pressure on thermal interface layer 718 through the die structure and the package base to form metal-to-metal bonding. In some embodiments, the bonding process may also include alignment, die placement, and a reflow process. The exposed wirings on the back surface (e.g., the surface opposite of semiconductor die 704) of the die surface may then be bonded with the corresponding I/O's of package base 714 through thermal interface layer 718.

At step 810, the package lid is bonded onto the package base and the die structure. As shown in FIG. 7E, a thermal interface material layer 726 may be dispensed on surface finish layer 724, and a thermal interface material layer 728 may be dispensed over semiconductor die 728. Thermal interface material layers 726 and 728 may include at least one of sintered gold, sintered silver, and sintered copper. In some embodiments, the dispensing of thermal interface material layers 726 and 728 may be similar to the dispensing of thermal interface layer 718.

As shown in FIG. 7F, a package lid 730 may be placed over, and bonded to the die structure and the package base. Package lid 730 may be in contact with and pressed against thermal interface material layers 726 and 728, which formed thermal interface layers 736 and 738, respectively. In some embodiments, the placing and bonding of package lid 730 includes applying heat and pressure onto thermal interface material layers 726 and 728 to form metal-to-metal bonding, and may include a curing process.

In some embodiments, a metal shielding layer and/or a molding layer are formed on package lid 730. FIG. 7G shows a scenario in which both a metal shielding layer 732 and a molding layer 734 are both formed. In some embodiments, metal shielding layer 732 includes a first portion 732-1 in contact with a side surface of package lid 730 and a second portion 732-2 in contact with a top surface of package lid 730. In some embodiments, molding layer 734 includes a first portion 734-1 in contact with first portion 732-1 and a second portion 734-2 in contact with second portion 732-2. In some embodiments, metal shielding layer 732 includes a copper-stainless steel-copper (Cu/SUS/CU) structure, and is deposited using sputtering shielding. In some embodiments, molding layer 734 is deposed using film-assisted molding. In some embodiments, no metal shielding layer is formed.

In some embodiments, 732 represents a molding layer (e.g., 732-1 and 732-2 representing the first and second portions of the molding layer), and 734 represents a metal shielding layer (e.g., 734-1 and 734-2 representing the first and second portions of the metal shielding layer). For example, the molding layer may be formed to be in contact with package lid 730, and the metal shielding layer may be formed to fully or partially cover the molding layer.

In an example, method 800 entails attaching high-power GaN or GaAs dies to a top substrate through flux print or dipping, followed by reflow, cleaning, and an underfill process to ensure the integrity of the stacked FC die. After surface mount technology (SMT) and underfilling, the module (e.g., die structure) is attached to the SiC or Ceramic base using sintered Au. The SiC or Ceramic base substrate can be processed separately, with through vias filled with conductive materials, and surface finished to create the interconnect (IO) at the package base. The packaging footprint can be in the land grid array (LGA) format.

Subsequently, an oversized SiC heat spreader with cavity walls is attached to the top of the die and base substrate using high thermal conductivity sintering material such as sintered Au. Additionally, film-assisted molding can be applied to further enhance the cavity package's hermeticity against leaks and integrity of the heat spreader. This results in a package with an exposed heat spreader on top and a cavity package surrounded by SiC as a wall, top lid, and SiC or Ceramic bottom substrate. This configuration brings the cavity package closer to the hermetic level, as SiC or ceramic does not absorb moisture or water.

The disclosed approach allows customers to attach heat sinks to the top, while the bottom package can be mounted on a PCB. This configuration enables top-side cooling through the heat spreader and creates a cavity that approaches near-hermetic levels. Overall, this disclosure enhances heat transfer within the package and improves the RF performance of the cavity package. Additionally, this cavity package can undergo moisture sensitivity level (MSL) preconditioning and gross leak testing, eliminating the need for board-level washing after SMT assembly.

Those skilled in the art will recognize improvements and modifications to the preferred embodiments of the present disclosure. All such improvements and modifications are considered within the scope of the concepts disclosed herein and the claims that follow.

1. A packaging device, comprising:
a package base;
a die structure disposed over the package base; and
a package lid over the die structure, and thermally coupled with the die structure and the package base.

2. The packaging device of claim 1, wherein the package lid comprises a hermetic material having a thermal conductivity of at least 180 W/(m·K).

3. The packaging device of claim 1, wherein the package lid comprises at least one of silicon carbide, ceramic, or copper.

4. The packaging device of claim 1, wherein the package base comprises at least one of silicon carbide, ceramic, or copper.

5. The packaging device of claim 1, further comprising a first thermal interface layer disposed between the die structure and the package lid, wherein the first thermal interface layer is in contact with the die structure and the package lid.

6. The packaging device of claim 5, wherein the first thermal interface layer comprises at least one of sintered gold, sintered silver, or sintered copper.

7. The packaging device of claim 1, further comprising a second thermal interface layer disposed between the die structure and the package base, wherein the second thermal interface is in contact with the die structure and the package base.

8. The packaging device of claim 7, wherein the second thermal interface layer comprises at least one of sintered gold, sintered silver, or sintered copper.

9. The packaging device of claim 7, wherein the second thermal interface layer comprises an interposer layer that electrically connects the die structure and the package base.

10. The packaging device of claim 1, further comprising a third thermal interface layer disposed between the package lid and the package base, wherein the third thermal interface is in contact with the package lid and the package base.

11. The packaging device of claim 10, wherein the third thermal interface layer comprises at least one of sintered gold, sintered silver, or sintered copper.

12. The packaging device of claim 1, further comprising a molding layer surrounding and in contact with a side surface of the package lid.

13. The packaging device of claim 12, further comprising a metal shielding layer covering the molding layer.

14. The packaging device of claim 1, further comprising:
a metal shielding layer in contact with a top surface and a side surface of the package lid; and
a molding layer covering the metal shielding layer.

15. The method of claim 14, wherein the metal shielding layer comprise a copper-stainless steel-copper structure.

16. The packaging device of claim 1, wherein the die structure comprises:
a semiconductor die;
a package substrate; and
an interconnect layer between the semiconductor die and the package substrate, wherein the interconnect layer electrically connects the semiconductor die and the package substrate.

17. The packaging device of claim 16, wherein the interconnect layer comprises a plurality of soldering structures without an underfill layer.

18. The packaging device of claim 1, wherein the package base comprises a plated heat spreader (PHS) substrate.

19. The packaging device of claim 1, wherein the package base comprises a lead frame or a copper substrate.

20. A method for forming a packaging device, comprising:
forming a die structure;
forming a package base;
forming a package lid;
bonding the die structure onto the package base; and
bonding the package lid onto the package base and the die structure.
